(19) United States
(12) Patent Application Publication
(10) Pub. No.: US 2026/0060026 A1
(43) Pub. Date: Feb. 26, 2026

(54) CLEANING BRUSH AND WAFER CLEANING APPARATUS INCLUDING THE SAME

(71) Applicant: SAMSUNG ELECTRONICS CO., LTD., Suwon-si (KR)

(72) Inventors: Seungmahn LEE, Suwon-si (KR); Seonmin Yun, Suwon-si (KR); Choongoang Kim, Suwon-si (KR)

(73) Assignee: SAMSUNG ELECTRONICS CO., LTD., Suwon-si (KR)

(21) Appl. No.: 19/029,957

(22) Filed: Jan. 17, 2025

(30) Foreign Application Priority Data
Aug. 22, 2024 (KR) 10-2024-0112919

(51) Int. Cl. H01L 21/67

(52) U.S. Cl. CPC H01L 21/67046; H01L 21/67051

(57) ABSTRACT

A cleaning brush includes a body having a truncated cone shape and having a first region configured to contact a central region of a wafer and a second region configured to contact an edge region of the wafer, a plurality of first nodules on the first region and protruding outwardly from the body, and a plurality of second nodules on the second region and protruding outwardly from the body, where a first ratio of a number of the plurality of first nodules to a surface area of the first region is smaller than a second ratio of a number of the plurality of second nodules to a surface area of the second region.

### CROSS-REFERENCE TO RELATED APPLICATION

This application is based on and claims priority to Korean Patent Application No. 10-2024-0112919, filed on Aug. 22, 2024, in the Korean Intellectual Property Office, the disclosure of which are incorporated by reference herein in its entirety.

### BACKGROUND

Example embodiments of the disclosure relate to a cleaning brush and a wafer cleaning apparatus including the same.

In general, a conductor, a semiconductor and/or an insulator may be continuously deposited on a silicon wafer to form integrated circuits. The respective layers may be deposited and then etched to impart circuit characteristics. As a series of layers are continuously deposited and etched, an exposed surface of a wafer may be increasingly rough, and a chemical mechanical polishing (CMP) process may be used to smooth the rough exposed surface of the wafer.

After the CMP process, particles such as polishing products, slurry, and the like may be left on the surface of the wafer. To remove the particles such as the polishing products, the slurry, and the like, a cleaning process has to be performed on the surface of the wafer. The cleaning process may include a cleaning process using a brush, a cleaning process using ultrasonic, and a wafer dry process. The cleaning process using the brush may refer to a process of brushing the surface of the wafer using at least one or more roll brushes. The cleaning power in the cleaning process using the brush may depend on a material, shape and/or configuration of the brush.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a cleaning brush and a wafer cleaning apparatus that may be capable of providing uniform cleaning power to an entire region of a wafer.

Additional aspects will be set forth in part in the description which follows and, in part, will be apparent from the description, or may be learned by practice of the presented embodiments.

According to an aspect of an example embodiment, a cleaning brush may include a body having a truncated cone shape and having a first region configured to contact a central region of a wafer and a second region configured to contact an edge region of the wafer, a plurality of first nodules on the first region and protruding outwardly from the body, and a plurality of second nodules on the second region and protruding outwardly from the body, where a first ratio of a number of the plurality of first nodules to a surface area of the first region is smaller than a second ratio of a number of the plurality of second nodules to a surface area of the second region.

According to an aspect of an example embodiment, a cleaning brush may include a body having a truncate cone shape and configured to rotate about a rotation axis in a first direction, where the body includes a first end and a second end opposite the first end, a plurality of first nodules on a first virtual circle having a first diameter, the first virtual circle being positioned at a first distance from the first end of the body, and a plurality of second nodules on a second virtual circle having a second diameter that is greater than the first diameter, the second virtual circle being positioned at a second distance from the first end of the body that is greater than the first distance, where the first distance is 60% or less of a radius of a wafer, the plurality of first nodules and the plurality of second nodules are configured to contact a surface of the wafer, and a ratio of a sum of lengths of upper surfaces of the plurality of first nodules to a circumference of the first virtual circle is smaller than a ratio of sum of lengths of upper surfaces of the plurality of second nodules to a circumference of the second virtual circle.

According to an aspect of an example embodiment, a wafer cleaning apparatus may include a spray nozzle configured to supply a cleaning solution onto a wafer, a first cleaning brush configured to clean a first surface of the wafer, and a first driver configured to rotate the first cleaning brush in a first direction, where the first cleaning brush includes a body having a truncated cone shape and having a first region configured to contact a central region of the wafer and a second region configured to contact an edge region of the wafer, a plurality of first nodules on the first region and protruding outwardly from the body, and a plurality of second nodules on the second region and protruding outwardly from the body, and where a first ratio of a number of the plurality of first nodules to a surface area of the first region is smaller than a second ratio of a number of the plurality of second nodules to a surface area of the second region.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a semiconductor manufacturing apparatus according to one or more embodiments;

FIG. 2 is a diagram illustrating a first brush of a wafer cleaning apparatus according to one or more embodiments;

FIG. 3 is a diagram illustrating a cleaning brush included in a wafer cleaning apparatus according to one or more embodiments;

FIG. 4 is a cross-sectional view of the cleaning brush taken along line A-A of FIG. 3 according to one or more embodiments;

FIG. 5 is a cross-sectional view of the cleaning brush taken along line B-B of FIG. 3 according to one or more embodiments;

FIG. 6 is a cross-sectional view of the cleaning brush taken along line C-C of FIG. 3 according to one or more embodiments;

FIG. 7 is a cross-sectional view of the cleaning brush taken along line D-D of FIG. 3 according to one or more embodiments;

FIG. 8 is a graph illustrating implementation of nodules disposed on a cleaning brush according to one or more embodiments;

FIG. 9 is a diagram illustrating a cleaning brush according to one or more embodiments;

FIG. 10 is a diagram illustrating a cleaning brush according to one or more embodiments; and

FIG. 11 is a diagram illustrating a wafer cleaning apparatus according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

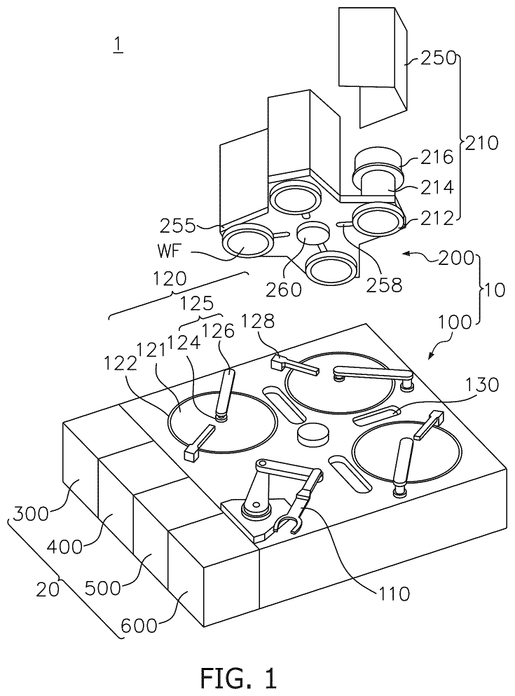

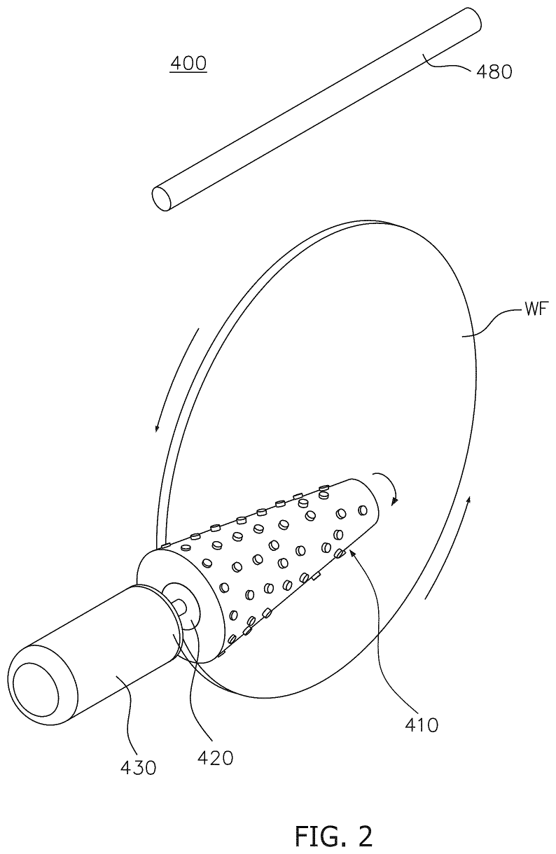

FIG. 1 is a perspective view illustrating a semiconductor manufacturing apparatus according to one or more embodiments. FIG. 2 is a diagram illustrating a first brush of a wafer cleaning apparatus according to one or more embodiments.

Referring to FIG. 1, a semiconductor manufacturing apparatus 1 may include a wafer polishing apparatus 10 configured to polish a wafer WF and a wafer cleaning apparatus 20 configured to clean a polished surface of the wafer WF.

The wafer polishing apparatus 10 may include a lower machine base 100 and a carousel 200. The lower machine base 100 may include a transfer station 110, a polishing station 120, and a cleaning station 130.

The transfer station 110 may transfer the wafer WF, to which one process is finished, to another station in which another process is to be performed. The transfer station 110 may be positioned on the same plane as the polishing station 120. The transfer station 110 may transfer the wafer WF polished in the polishing station 120 to another polishing station 120, and transfer the wafer WF to which the polishing process is finished to the wafer cleaning apparatus 20. It is illustrated in FIG. 1 that three polishing stations 120 are included in the lower machine base 100, but embodiments are not limited thereto.

The polishing station 120 may include a polishing pad 121, a platen 122, a pad conditioner 125, and a slurry arm 128. The polishing pad 121 may be disposed on the platen 122 to be supported by the platen 122. The polishing pad 121 may rotate together with the platen 122 during the process. The polishing pad 121 may have a circular plate with a rough top surface. The top surface of the polishing pad 121 may directly contact the wafer WF to mechanically polish the wafer WF.

The platen 122 may be coupled to a driving motor through a platen driving shaft. In a general polishing process, the driving motor may rotate the platen 122 at 30 to 210 revolutions per minute. However, embodiments are not limited thereto. Diameters of the polishing pad 121 and the platen 122 may be approximately twice as large as a diameter of wafer WF.

The pad conditioner 125 may include a conditioner head 124 and a rotation arm 126. The conditioner head 124 may rotate independently from the rotation arm 126. The rotation arm 126 may support the conditioner head 124 and simultaneously allow the conditioner head 124 to be positioned on the polishing pad 121. While the polishing pad 121 rotates, the pad conditioner 125 may maintain a state of the polishing pad 121 so that the wafer WF is effectively polished.

The slurry arm 128 may be provided to extend over the polishing pad 121 in the outside of the polishing pad 121. The slurry arm 128 may supply the slurry onto the top surface of the polishing pad 121. The slurry arm 128 may be coupled to a slurry supply apparatus (not shown). The slurry may include a reactant (for example, deionized (DI) water for oxidizing polishing), abrasive particles (for example, silicon dioxide for oxidizing polishing), and a chemical reaction catalyst (for example, potassium hydroxide for oxidizing polishing). The slurry may be provided to cover and wet the overall of the polishing pad 121. The slurry arm 128 may include a plurality of cleaning spray nozzles. The cleaning spray nozzle may clean the polishing pad 121 with high pressure in a finishing stage of the polishing process.

The cleaning station 130 may be positioned between adjacent polishing stations 120. A plurality of cleaning stations 130 may be provided. The cleaning station 130 may clean the wafer WF while the wafer WF moves from one polishing station 120 to another polishing station 120.

The carousel 200 may include a polishing head system 210 and a central column 260. The carousel 200 may be disposed over the lower machine base 100. The carousel 200 may be supported by the central column 260 and may rotate about the central column 260 by a carousel motor.

The carousel 200 may include four polishing head systems 210. The polishing head systems 210 may be positioned to be spaced apart by the same angle with respect to the center of the carousel 200, respectively.

Three of the polishing head systems 210 may accommodate and maintain the wafer WF and pressurize the wafer WF against the polishing pad 121 on the platen 122 to polish the wafer WF. The remaining one of the polishing head systems 210 may receive the wafer WF to which the polishing process is completed and transfer the wafer WF onto the transfer station 110.

The polishing head system 210 may include a polishing head 212, a spindle 214, a motor 216, and a housing 250. The polishing head 212 may independently rotate around an axis thereof, and reciprocate laterally within an opening 258 formed below the housing 250. The polishing head 212 may be provided approximately in a cylindrical shape. The polishing head 212 may be provided to have different circumferences in a lower region and an upper region. For example, the polishing head 212 may be provided to have a larger circumference in a lower portion than in an upper portion. The circumference of the polishing head 212 may be gradually reduced up to a portion to which the spindle 214 is coupled.

The spindle motor 214 may couple the motor 216 to the polishing head 212. The spindle 214 may be provided in a cylindrical shape. One spindle 214 and one motor 216 may be provided in the polishing head 212. The motor 216 may provide power which rotates the polishing head 212 during the process.

The housing 250 may be provided to cover the spindle 214 and the motor 216. A housing support plate 255 may be provided in a bottom surface of the housing 250. The housing support plate 255 may include four openings 258 which radially extend and are spaced apart from each other by 90 degrees. The polishing head 212 may laterally reciprocate within the opening 258. The opening 258 may be a closed end or an opened end.

The wafer cleaning apparatus 20 may include a megasonic cleaning apparatus 300, a first brush 400, a second brush 500, and a drying apparatus 600. Impurities including particles may be adhered to a top surface of the wafer WF to which the polishing process is finished. The wafer cleaning apparatus 20 may remove the impurities in the surface of the wafer WF to prevent scratches from occurring in the surface of the wafer WF.

The megasonic cleaning apparatus 300 may clean the wafer WF using megasonic energy. The megasonic cleaning apparatus 300 may apply the megasonic energy to DI water to form microbubbles and clean the particles on the surface of the wafer WF while the microbubbles burst onto the surface of the wafer WF. The megasonic energy may have frequency 10 to 50 times higher than ultrasonic energy. For example, the megasonic energy may have the frequency of 200 kHz to 1000 kHz. The wafer WF may rotate in the megasonic cleaning apparatus 300 to improve the cleaning power.

The description of the second brush 500 may be similar to that of the first brush 400. Hereinafter, description for the brush will be centered on the first brush 400.

Referring to FIGS. 1 and 2, the first brush 400 may include a cleaning brush 410, a brush core 420, a driver 430, and a spray nozzle 480.

The cleaning brush 410 may be disposed on the surface of the wafer WF. The cleaning brush 410 may clean the surface of the wafer WF. The cleaning brush 410 may rotate in a first direction (for example, clockwise) to clean the particles on the surface of the wafer WF. The brush core 420 may couple the driver 430 and the cleaning brush 410. The driver 430 may rotate the cleaning brush 410.

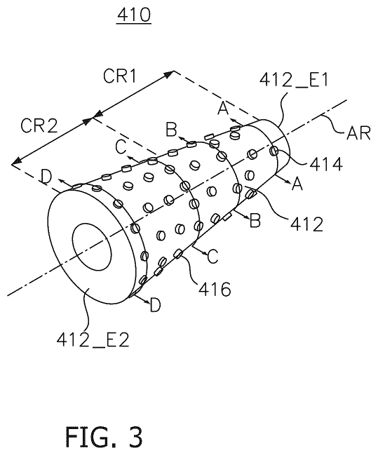

In one or more embodiments, a length of the cleaning brush 410 may be greater than a radius of the wafer WF. The cleaning brush 410 may be disposed from the center of the wafer WF to an edge of the wafer WF. As the wafer rotates, the cleaning brush 410 may clean an entire surface of the wafer WF. The cleaning brush will be descried in detail with reference to FIGS. 3 to 7.

A wafer driver may rotate the wafer WF. In one or more embodiments, the wafer WF may rotate in a second direction (for example, counterclockwise) different from the first direction in which the cleaning brush 410 rotates. The rotation directions of the wafer WF and the cleaning brush 410 may be opposite to each other. For example, the direction of linear velocity of the wafer WF may be opposite to the direction of linear velocity of the cleaning brush 410 in a surface of the wafer WF which is contacts the cleaning brush 410. In the surface that the wafer WF that contacts the brush 410, the direction of the linear velocity in the wafer WF may be an upward direction and the direction of the linear velocity in the cleaning brush 410 may be in a downward direction.

The spray nozzle 480 may supply a cleaning solution to the wafer WF while the cleaning brush 410 cleans the wafer WF. For example, the cleaning solution may include any one of DI water, ammonia water (NH₄OH), and hydrofluoric acid (HF), but the type of cleaning solution is not limited thereto. The wafer WF and the cleaning brush 410 may simultaneously rotate, and thus the wafer WF may be efficiently cleaned.

It is illustrated in FIG. 2 that the wafer WF is disposed in perpendicular to a ground, but embodiments are not limited thereto. For example, the wafer WF may be disposed in parallel to the ground or may be disposed at an acute angle to the ground.

The drying apparatus 600 may dry the cleaning solution left on the surface of the wafer WF. For example, the drying apparatus 600 may be a spin dryer, an isopropyl alcohol (IPA) vapor dryer, or a Marangoni dryer. The spin dryer may dry the wafer WF using centrifugal force caused by rotation. The IPA vapor dryer may dry the wafer WF using a method which replaces DI water adsorbed on the wafer WF using vapor generated by heating isopropyl alcohol (IPA) as an organic solvent at a high temperature of 180 degrees or more. The Marangoni dryer may use a method which forms an IPA vapor layer on a top surface of DI wafer, lift the wafer WF above the top surface of the DI water, and dry the wafer WF using the difference in top surface tension between the DI water and the IPA vapor layer.

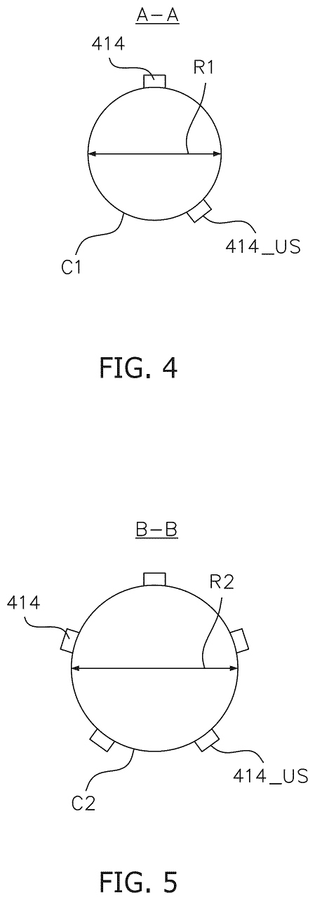

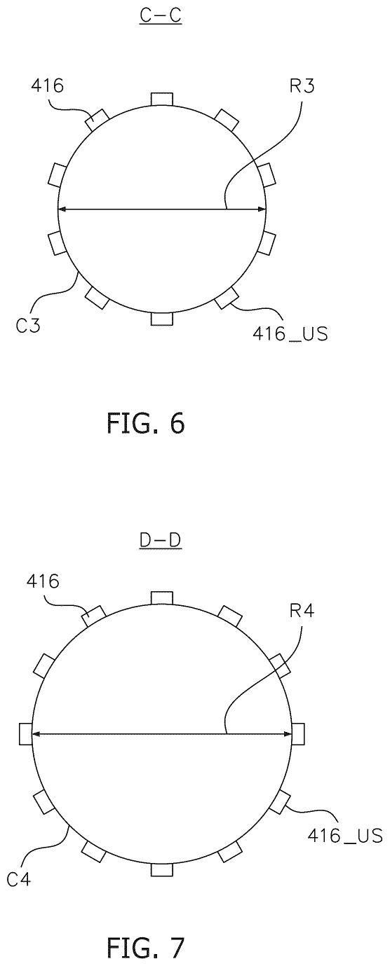

FIG. 3 is a diagram illustrating a cleaning brush included in the wafer cleaning apparatus of FIG. 2 according to one or more embodiments. FIG. 4 is a cross-sectional view of the cleaning brush taken along line A-A of FIG. 3 according to one or more embodiments. FIG. 5 is a cross-sectional view of the cleaning brush taken along line B-B of FIG. 3 according to one or more embodiments. FIG. 6 is a cross-sectional view of the cleaning brush taken along line C-C of FIG. 3 according to one or more embodiments. FIG. 7 is a cross-sectional view of the cleaning brush taken along line D-D of FIG. 3 according to one or more embodiments.

Referring to FIGS. 3 to 7, the cleaning brush 410 may include a body 412 and a plurality of nodules 414 and 416 disposed on the body 412.

The cleaning brush 410 may include the body 412 having a truncated cone shape. The body 412 may include a first end 412_E1 and a second end 412_E2. The first end 412_E1 may face the second end 412_E2 in a direction AR of the rotation shaft. A diameter of the first end 412_E1 may be smaller than that of the second end 412_E2. For example, a diameter of the body 412 may be linearly increased from the first end 412_E1 toward the second end 412_E2. A distance from the first end 412_E1 to the second end 412_E2 of the body 412 may be equal to or greater than the radius of the wafer (for example, WF of FIG. 2).

The body 412 may include a first region CR1 and a second region CR2. The first region CR1 may clean a central region of the wafer (WF of FIG. 2). The second region CR2 may clean an edge region of the wafer. For example, a diameter of the central region of the wafer WF may be 40% to 60% of the diameter of the wafer WF, but embodiments are not limited thereto. The edge region of the wafer WF may be a remaining portion of the wafer WF other than the central region of the wafer WF.

The plurality of nodules 414 and 416 may be disposed in an outer surface of the body 412. The plurality of nodules 414 and 416 may protrude from the outer surface of the body 412. The plurality of nodules 414 and 416 may include an elastic material. For example, the plurality of nodules 414 and 416 may include at least one of polyvinyl alcohol (PVA), polyacrylamide, urea-formaldehyde resins, melamine-formaldehyde resins, and carboxymethyl cellulose (CMC).

It is illustrated that the nodules 414 and 416 have a circular shape, but embodiments are not limited thereto. For example, the nodules 414 and 416 may have an oval shape, a cross shape, a bar shape, a round bar, and the like.

The plurality of nodules 414 and 416 may include a first nodule 414 disposed in the first region CR1 and a second nodule 416 disposed in the second region CR2. A plurality of first nodules 414 may be disposed in the first region CR1. A plurality of second nodules 416 may be disposed in the second region CR2. Hereinafter, description for the arrangement of the first nodule 414 and the second nodule 416 will be made in detail.

The first nodules 414 may be disposed to be spaced apart along a circumference of the outer surface of the body 412 in the first region CR1. The second nodules 416 may be disposed to be spaced apart along the circumference of the outer surface of the body 412 in the second region CR2. The density of the plurality of first nodules 414 disposed in the first region CR1 may be smaller than the density of the plurality of second nodules 416 disposed in the second region CR2. That is, a ratio of the number of first nodules 414 to a surface area of the first region CR1 may be smaller than a ratio of the number of second nodules 416 to a surface area of the second region CR2.

The density (i.e., corresponding to the ratio described above) of the plurality of first nodules 414 in the first region CR1 may be increased farther away from the first end 412_E1. For example, the increase in the density may refer to an increase of the ratio of nodules to the surface area of the region. Thus, the ratio of first nodules 414 to the surface area of region CR1 may increase from the first end 412_E1 to the second end 412_E2. That is, the amount of contact between the nodules and the wafer may increase from the first end 412_E1 to the second end 412_E2. With respect to the virtual circles, due to the distribution of the nodules throughout the body 412, the amount of contact between the body 412 and the wafer increases as the diameter of a virtual circle increases. For example, the amount of contact between the nodules 414 along virtual circle A and the wafer may be less than the amount of contact between nodules 414 along virtual circle B and the wafer, as virtual circle B has a larger diameter than virtual circle A.

Furthermore, the increase in the density (e.g., with reference to the first region CR1) may refer to a contact length of the first nodules 414 disposed on a virtual circle spaced apart from the first end 412_E1 increasing as the distance of the virtual circle from the first end 412_E1 increases. Thus, in some examples, the contact length may refer to a sum of cross-sectional lengths of upper surfaces of the nodules taken along a cross-section corresponding to a virtual circle. For example, referring to FIG. 3, FIG. 5 and FIG. 7, FIG. 5 shows a cross-sectional view of virtual circle B of FIG. 3, and FIG. 7 shows a cross-sectional view of virtual circle D of FIG. 3. The contact length of FIG. 5 corresponds to a sum of lengths of upper surfaces 414_US of the nodules 414 along virtual circle B in the corresponding cross-sectional view of FIG. 5, and the contact length of FIG. 7 corresponds to a sum of lengths of upper surfaces 416_US of the nodules 416 along virtual circle D in the corresponding cross-sectional view of FIG. 7. As the diameter of the virtual circles increases, the contact lengths increase. Thus, the ratio of the contact length may refer to a ratio of total contact lengths of the nodules 414 and 416 disposed on a circumference of the circle to the circumference of the circle. The contact length may be a contact length between top surfaces 414_US and 416_US of the nodules 414 and 416 and the wafer.

In other words, a number of nodules are disposed along a virtual circle, and these nodules have an upper surface that contacts a wafer during cleaning. In a cross-sectional view of said virtual circle, the upper surfaces of these nodules have a length (e.g., a length in a radial direction). Thus, the “contact length” of a virtual circle may refer to a sum (or total) of lengths of upper surfaces of nodules along said virtual circle as measured in a cross-sectional view of said virtual circle. Further, the “ratio of the contact length” may refer to a ratio of the sum (or total) of lengths of the upper surfaces of the nodules along said virtual circle as measured in a cross-sectional view of said virtual circle, to the circumference of said virtual circle. Accordingly, a “contact length of a virtual circle” may indicate a sum of lengths (e.g., radial lengths) of upper surfaces of nodules along said virtual circle as measured from the perspective of the cross-sectional view along said virtual circle. Furthermore “a ratio of a contact length of a virtual circle” may indicate a ratio of the sum of lengths of upper surfaces of nodules along said virtual circle as measured from the perspective of the cross-sectional view along said virtual circle, to the circumference of said virtual circle.

In one or more embodiments, a first circle C1 and a second circle C2 may be disposed in the first region CR1. The first circle C1 and the second circle C2 may be virtual circles. As described herein, the virtual circles may correspond to predetermined or arbitrary positions in various regions of the body 412 of the brush 410. Thus, the virtual circles may also be referred to as positions having a diameter. The first circle C1 may be disposed to be spaced apart from the first end 412_E1 by a first distance. The first circle C1 may have a first diameter R1. The second circle C2 may be disposed to be spaced apart from the first end 412_E1 by a second distance greater than the first distance. The second circle C2 may have a second diameter R2 greater than the first diameter R1. The second distance may be 60% or less of the radius of the wafer.

When cleaning the wafer, the top surface 414_US of the first nodule 414 may contact the wafer. The number of first nodules 414 disposed on the first circle C1 may be two. The number of first nodules 414 disposed on the second circle C2 may be five. As the number of first nodules 414 disposed on the virtual circle is increased, the contact lengths of the plurality of first nodules 414 (e.g., the sum of the lengths of the upper surfaces of the plurality of nodules) may be increased.

The ratio of the contact length of the plurality of first nodules 414 disposed on the first circle C1 to the circumference of the first circle C1 may be smaller than the ratio of the contact length of the plurality of first nodules 414 disposed on the second circle C2 to the second circle C1. That is, as the distance from the first end 412_E1 in the first region CR1 increases, the contact length and the ratio of the contact length to circumferences of virtual circles may increase. In other words, the number of nodules along a virtual circle of the body 412 may increase as the diameter of the virtual circle increases.

In one or more embodiments, in the first region CR1, the increased rate of the contact length and the ratio of the contact length of the plurality of first nodules 414 to the circumferences of the virtual circles may be predetermined. For example, at a point spaced apart by a specific distance from the center of the wafer WF, relative velocity between the linear velocity of the wafer WF and the linear velocity of the cleaning brush 410 may be determined. Next, the ratio of the contact length of the first nodules 414 may be determined so that the product of the relative velocity between the linear velocity of the wafer WF and the linear velocity of the cleaning brush 410, and the ratio of the contact length of the plurality of first nodules 414 may be linearly increased in proportion to the specific distance from the center of the wafer WF. For example, “linear increase” may indicate a tendency of liner increase.

In one or more embodiments, the ratio of the contact length of the plurality of first nodules 414 disposed on the virtual circle disposed in the first region CR1 (for example, the first circle C1 and the second circle C2) to the circumference of the virtual circle may be 10% or more.

The density of the plurality of second nodules 416 in the second region CR2 (i.e., the ratio of the number of the plurality of second nodules 416 to a surface area of the second region CR2) may be constant. The density of the plurality of second nodules 416 in the second region CR2 may be constant or similar as a distance from the first end 412_E1 increases. For example, constant or similar density may indicate that the ratio of the contact length of the second nodules 416 disposed on the virtual circle to the circumference of said virtual circle is constant or similar at various distances within the second region CR2 from the first end 412_E1. Similar may indicate that the ration is included within a predetermined range.

In one or more embodiments, a third circle C3 and a fourth circle C4 may be disposed in the second region CR2. The third circle C3 and the fourth circle C4 may be virtual circles. The third circle C3 may be disposed to be spaced apart by a third distance from the first end 412_E1. The third circle C3 may have a third diameter R3. The fourth circle C4 may be disposed to be spaced apart by a fourth distance greater than the third distance from the first end 412_E1. The fourth circle C4 may have a fourth diameter R4 greater than the third diameter R3.

When cleaning the wafer, the top surface 416_US of the second nodule 416 may contact the wafer. The number of second nodules 416 disposed on the third circle C3 may be ten. The number of second nodules 416 disposed on the fourth circle C4 may be twelve. As the number of second nodules 416 disposed on the virtual circle is increased, the contact length of the plurality of second nodules 416 may be increased.

The ratio of the contact length of the plurality of second nodules 416 disposed on the third circle C3 to the circumference of the third circle C3 may be the same as or similar to the ratio of the contact length of the plurality of second nodules 416 disposed on the fourth circle C4 to the circumference of the fourth circle C4. The contact length of the plurality of second nodules 416 disposed on the third circle C3 (e.g., the length of upper surfaces of the nodules 416 on the third circle C3 when viewed in cross-section taken along the third circle C3) may be the same as or similar to the contact length of the plurality of second nodules 416 disposed on the fourth circle C4 (e.g., the length of upper surfaces of the nodules 416 on the fourth circle C4 when viewed in cross-section taken along the fourth circle C4). For example, as the distance from the first end 412_E1 in the second region CR2 increases, the circumference of virtual circles taken in the second region CR2 may increase, but the contact length of the second nodules 416 may be the same or similar at various positions along the body 412 in the second region CR2.

In one or more embodiments, the ratio of the contact length of the upper surfaces of the plurality of second nodules 416 disposed on the virtual circle (for example, the third circle C3 and the fourth circle C4) disposed in the second region CR2 to the circumference of the virtual circle may be 40% or more.

In one or more embodiments, the first nodule 414 and the second nodule 416 may have the same shape as each other. For example, an area of the top surface 414_US of the first nodule 414 may be the same as an area of the top surface 416_US of the second nodule 416.

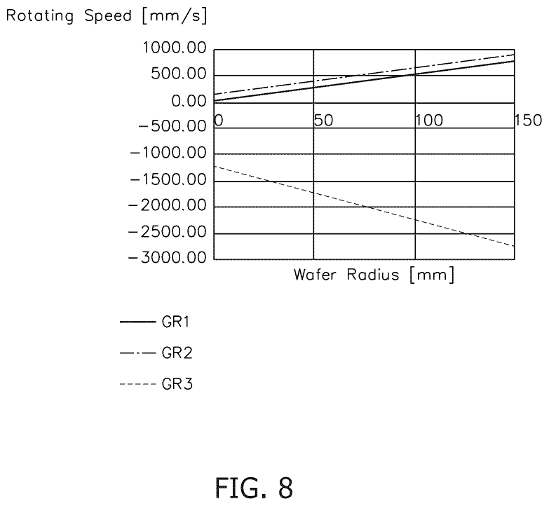

FIG. 8 is a graph illustrating implementation of nodules disposed on a cleaning brush according to one or more embodiments.

Referring to FIG. 8, the graph illustrates rotating speed of a wafer, rotating speed of a cleaning brush, and a difference between the rotating speeds of the wafer and the cleaning brush, according to a wafer radius, respectively. FIG. 8 is described in relation to Equation (1) below.

$$Brush Scrubbing intensity [ J / {m}^{2} ] = \frac{E}{A} = \frac{Power [ W ] \times Δ t}{A} = \frac{{μ}_{k} \times {F}_{N} \times v \times Δ t}{A} = {μ}_{A} \times P \times v \times Δ t \qquad ( 1 )$$

For example, the scrub intensity of the cleaning brush may be defined as E/A. “E” may correspond to an amount of scrub of the cleaning brush on the wafer, and “A” may be an area that the scrub of the cleaning brush occurs. The amount E of the scrub of the cleaning brush may be in proportion to the product of relative speed difference V between the wafer and the cleaning brush and the contact time T of the cleaning brush. “P” may be the contact pressure, and “p” may be constant.

A first line GR1 illustrates the rotating speed of the wafer according to the wafer radius. The rotating speed of the wafer according to the wafer radius may be increased as in the first line GR1. For example, as the wafer radius is increased, the linear velocity of the wafer may be increased. Because the body of the cleaning brush has a truncated cone shape, as the wafer radius is increased, the linear velocity of the wafer may also be increased.

A second line GR2 illustrates the rotating speed of the cleaning brush according to the wafer radius. As the wafer radius is increased, the rotating speed of the cleaning brush may be increased as in the second line GR2. For example, as the wafer radius is increased, the linear velocity of the cleaning brush may be increased. In one or more embodiments, the difference between the linear velocity of the wafer and the velocity of the cleaning brush may be constantly maintained.

A third line GR3 illustrates the absolute value of the difference between the linear velocity of the wafer and the velocity of the cleaning brush according to the wafer radius. In one or more embodiments, as in the third line GR3, as the wafer radius is increased, the absolute value of the difference between the linear velocity of the wafer and the velocity of the cleaning brush may be increased.

The density of the nodule of the cleaning brush may correspond to the contact time between the nodule of the cleaning brush and the wafer. For example, when the density of the nodule of the cleaning brush is uniform, the contact time between the nodule and the wafer in the central region of the wafer may be greater than the contact time between the nodule and the wafer in the edge region of the wafer. The scrub intensity of the cleaning brush may be larger in the central region of the wafer than in the edge region of the wafer. Accordingly, the central region of the wafer may be excessively scrubbed as compared with the edge region of the wafer, and thus a portion of semiconductor elements formed in the central region of the wafer may be removed. Because the cleaning solution is sprayed onto the wafer to clean the wafer, the cleaning solution may not penetrate between the wafer and the cleaning brush when the wafer is excessively scrubbed.

However, in the cleaning brush used in the wafer cleaning apparatus according to one or more embodiments, the density of the nodule may be varied according to a distance from the end of the cleaning brush. For example, in the first region of the cleaning brush, as the distance from the first end is increased, the density of the nodule of the cleaning brush may be increased. In this example, the density of the nodule of the cleaning brush may be reduced toward the center of the wafer. The contact time of the nodule of the cleaning brush may be reduced in the center region of the wafer. Accordingly, the wafer may be cleaned with the uniform scrub intensity between the central region and the edge region of the wafer, and thus the semiconductor elements formed on the wafer may not be removed.

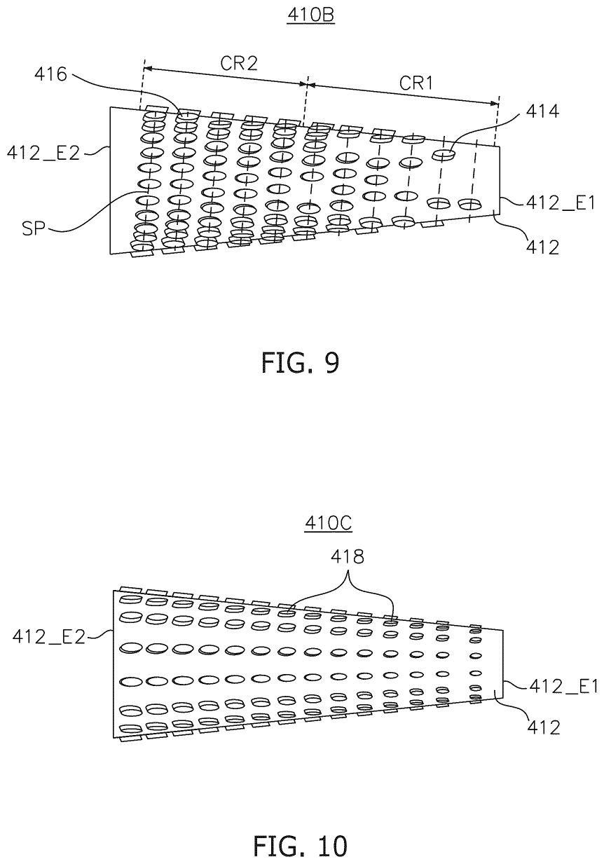

FIG. 9 is a diagram illustrating a cleaning brush according to one or more embodiments. For clarity, description for the cleaning brush will be centered on configurations different from those described in FIGS. 3 to 7.

Referring to FIG. 9, a cleaning brush 410B according to one or more embodiments may include a body 412 and a plurality of nodules 414 and 416 disposed on the body 412.

The cleaning brush 410B may include the body 412 having a truncated cone shape. The body 412 may include a first region CR1 and a second region CR2. The plurality of nodules 414 and 416 may include a plurality of first nodules 414 disposed in the first region CR1 and a plurality of second nodules 416 disposed in the second region CR2. The plurality of nodules 414 and 416 may be disposed along a virtual spiral SP which extends toward a second end 412_E2 of the body 412 from a first end 412_E1 of the body 412. Nodule arrangement points, which are disposed to be spaced apart at a constant interval, may be positioned on the virtual spiral SP.

In the first region CR1, the plurality of first nodules 414 may be disposed on the virtual spiral SP. The plurality of first nodules 414 may be disposed on the nodule arrangement points. In the first region CR1, there are portions of the nodule arrangement points in which the first nodules 414 are not disposed. The density of the nodules 414 may be increased farther away from the first end 412_E1. That is, the nodules 414 in the first region CR1 may be disposed to be spaced apart at non-constant intervals. In one or more embodiments, the non-constant intervals decrease at a constant rate, and thus the density of the number of nodules 414 in the first region CR1 increases as a distance from the end 412_E1 increases.

In the second region CR2, the plurality of second nodules 416 may be disposed. The plurality of second nodules 416 may be disposed on the nodule arrangement points. For example, the second nodules 416 may be disposed to be spaced apart at a constant interval on the second region CR2.

FIG. 10 is a diagram illustrating a cleaning brush according to one or more embodiments. For clarity, description for the cleaning brush will be centered on configurations different from those described in FIGS. 3 to 7.

Referring to FIG. 10, a cleaning brush 410C according to one or more embodiments may include a body 412 and a plurality of third nodules 418 disposed on the body 412.

The cleaning brush 410C may include the body 412 having a truncated cone shape. The body 412 may include a first end 412_E1 and a second end 412_E2 opposite the first end 412_E1.

The plurality of third nodules 418 may be disposed on an outer surface of the body 412. The plurality of third nodules 418 may protrude from the outer surface of the body 412. Sizes of the third nodules 418 may not be the same as each other. The sizes of the third nodules 418 may be varied according to distances in which the third nodules are disposed to be spaced apart from the first end 412_E1. For example, as the third nodule 418 is positioned farther away from the first end 412_E1, the size of the third nodule 418 may be increased. It is illustrated in FIG. 10 that the plurality of third nodules 418 are disposed in a row in a direction of from the first end 412_E1 toward the second end 412_E2, but embodiments are not limited thereto. For example, when viewed in the direction of from the first end 412_E1 toward the second end 412_E2, the plurality of third nodules 418 may be disposed in various manners (for example, zigzag manner). In one or more embodiments, the plurality of third nodules 418 may be disposed in a spiral manner as in FIG. 9 and the size of the third nodule 418 may be increased farther away from the first end 412_E1. That is, the size of the nodules nearer to the first end 412_E1 may be smaller than the size of the nodules further from the first end 412_E1. In other words, the size of the contact area of the nodules nearer to the first end 412_E1 may be smaller than the size of the contact area of the nodules further from the first end 412_E1

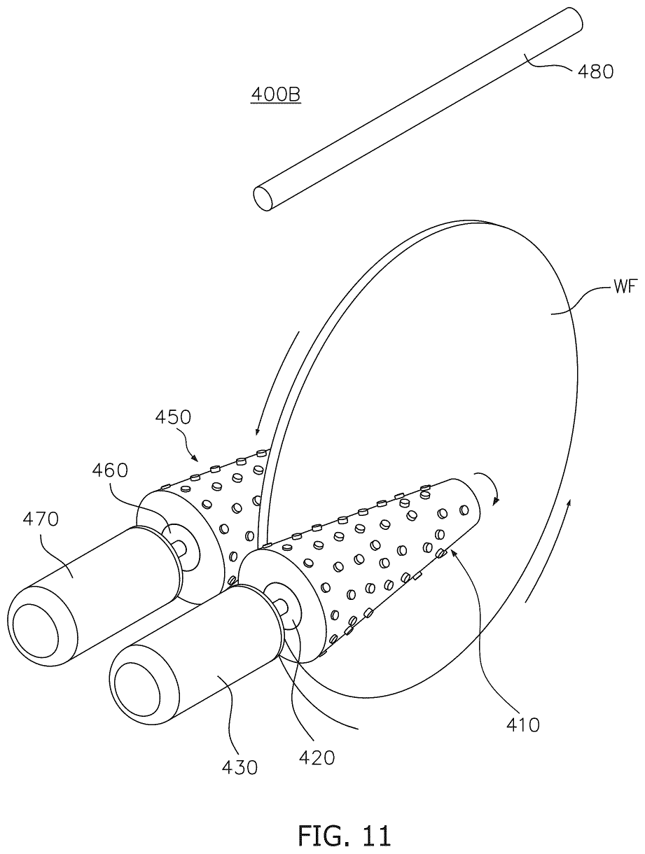

FIG. 11 is a diagram illustrating a wafer cleaning apparatus according to one or more embodiments. For clarity, description for the wafer cleaning apparatus will be centered on configurations different from those described in FIG. 2.

Referring to FIG. 11, a first brush 400B may include a first cleaning brush 410, a first brush core 420, a first driver 430, a second cleaning brush 450, a second cleaning brush core 460, a second driver 470, and a spray nozzle 480.

The first cleaning brush 410 may be disposed on a first surface of a wafer WF. The first cleaning brush 410 may clean the first surface of the wafer WF. The first cleaning brush 410 may rotate in a first direction (for example, clockwise) to clean particles on the first surface of the wafer WF. The first brush core 420 may couple the first driver 430 and the first cleaning brush 410. The first driver 430 may rotate the first cleaning brush 410 to the first direction.

The second cleaning brush 450 may be disposed on a second surface of the wafer WF. The second surface of the wafer WF may be a surface opposing the first surface. The second cleaning brush 450 may clean the second surface of the wafer WF. The second cleaning brush 450 may rotate in a second direction (for example, counterclockwise) to clean particles on the second surface of the wafer WF. However, embodiments are not limited thereto. For example, the second cleaning brush 450 may clean the particles on the second surface of the wafer WF while rotating in the first direction. The second brush core 460 may couple the second driver 470 and the second cleaning brush 450. The second driver 470 may rotate the second cleaning brush 450 to the first direction or the second direction. In one or more embodiments, the second driver 470 may be driven independently of the first driver 430.

According to one or more embodiments, the density of a plurality of first nodules disposed in a first region of a brush may be less than that of a plurality of second nodules disposed in a second region, and thus the brush may uniformly clean a central region and an edge region of a wafer.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A cleaning brush, comprising:
a body having a truncated cone shape and having a first region configured to contact a central region of a wafer and a second region configured to contact an edge region of the wafer;
a plurality of first nodules on the first region and protruding outwardly from the body; and
a plurality of second nodules on the second region and protruding outwardly from the body,
wherein a first ratio of a number of the plurality of first nodules to a surface area of the first region is smaller than a second ratio of a number of the plurality of second nodules to a surface area of the second region.

2. The cleaning brush as claimed in claim 1, wherein the body comprises a first end and a second end opposite the first end, and
wherein a diameter of the first end is smaller than a diameter of the second end.

3. The cleaning brush as claimed in claim 2, wherein the first ratio decreases toward the first end of the body.

4. The cleaning brush as claimed in claim 2, wherein the second ratio is constant.

5. The cleaning brush as claimed in claim 1, wherein a diameter of the central region of the wafer is 40% to 60% of an overall diameter of the wafer.

6. The cleaning brush as claimed in claim 1, wherein the body comprises a first end and a second end opposite the first end, and
wherein the plurality of first nodules and the plurality of second nodules are provided in a spiral configuration extending from the first end to the second end.

7. The cleaning brush as claimed in claim 1, wherein, based on the wafer rotating in a first direction, the body is configured to rotate on the wafer in a second direction different from the first direction.

8. The cleaning brush as claimed in claim 1, wherein the body comprises a first end and a second end opposite the first end, and
wherein a distance from the first end to the second end is greater than or equal to a radius of the wafer.

9. A cleaning brush comprising:
a body having a truncate cone shape and configured to rotate about a rotation axis in a first direction, wherein the body comprises a first end and a second end opposite the first end;
a plurality of first nodules on a first virtual circle having a first diameter, the first virtual circle being positioned at a first distance from the first end of the body; and
a plurality of second nodules on a second virtual circle having a second diameter that is greater than the first diameter, the second virtual circle being positioned at a second distance from the first end of the body that is greater than the first distance,
wherein the first distance is 60% or less of a radius of a wafer,
wherein the plurality of first nodules and the plurality of second nodules are configured to contact a surface of the wafer, and
wherein a ratio of a sum of lengths of upper surfaces of the plurality of first nodules to a circumference of the first virtual circle is smaller than a ratio of a sum of lengths of upper surfaces of the plurality of second nodules to a circumference of the second virtual circle.

10. The cleaning brush as claimed in claim 9, further comprising a plurality of third nodules on a third virtual circle having a third diameter that is greater than the first diameter and less than the second diameter, the third virtual circle being positioned at a third distance from the first end of the body that is greater than the first distance and less than the second distance,
wherein the second distance is 60% or less of the radius of the wafer, and
wherein the ratio of the sum of the lengths of the upper surfaces of the plurality of first nodules to the circumference of the first virtual circle is smaller than a ratio of a sum of lengths of upper surfaces of the plurality of third nodules to a circumference of the third virtual circle.

11. The cleaning brush as claimed in claim 9, further comprising a plurality of fourth nodules on a fourth virtual circle having a fourth diameter that is greater than the second diameter, the fourth virtual circle being positioned at a fourth distance from the first end of the body that is greater than the second distance,
wherein the second distance is greater than 60% of the radius of the wafer, and
wherein the ratio of the sum of the lengths of the upper surfaces of the plurality of second nodules to the circumference of the second virtual circle is the same as a ratio of a sum of lengths of upper surfaces of the plurality of fourth nodules to a circumference of the fourth virtual circle.

12. The cleaning brush as claimed in claim 9, wherein a size of a contact area of each of the plurality of first nodules is smaller than a size of a contact area of each of the plurality of second nodules.

13. The cleaning brush as claimed in claim 9, wherein the ratio of the sum of the lengths of the upper surfaces of the plurality of first nodules to the circumference of the first virtual circle is 10% or more.

14. The cleaning brush as claimed in claim 9, wherein the second distance is greater than 60% of the radius of the wafer, and
wherein the ratio of the sum of the lengths of the upper surfaces of the plurality of second nodules to the circumference of the second virtual circle is 40% or more.

15. The cleaning brush as claimed in claim 9, wherein the first direction is a direction that is different from a direction in which the wafer rotates.

16. The cleaning brush as claimed in claim 9, wherein the plurality of first nodules and the plurality of second nodules are provided in a spiral configuration extending from the first end of the body toward the second end of the body.

17. A wafer cleaning apparatus comprising:
a spray nozzle configured to supply a cleaning solution onto a wafer;
a first cleaning brush configured to clean a first surface of the wafer; and
a first driver configured to rotate the first cleaning brush in a first direction,
wherein the first cleaning brush comprises:
a body having a truncated cone shape and having a first region configured to contact a central region of the wafer and a second region configured to contact an edge region of the wafer;
a plurality of first nodules on the first region and protruding outwardly from the body; and
a plurality of second nodules on the second region and protruding outwardly from the body, and
wherein a first ratio of a number of the plurality of first nodules to a surface area of the first region is smaller than a second ratio of a number of the plurality of second nodules to a surface area of the second region.

18. The wafer cleaning apparatus as claimed in claim 17, further comprising:
a second cleaning brush configured to contact a second surface of the wafer opposite the first surface of the wafer; and
a second driver configured to rotate the second cleaning brush in a second direction different from the first direction.

19. The wafer cleaning apparatus as claimed in claim 17, wherein the body comprises a first end and a second end opposite the first end,
wherein a diameter of the first end is smaller than that of the second end, and
wherein the first ratio decreases toward the first end of the body.

20. The wafer cleaning apparatus as claimed in claim 17, wherein a diameter of the central region of the wafer is 40% to 60% of an overall diameter of the wafer.
